(19) United States
(12) Patent Application Publication
(10) Pub. No.: US 2025/0068821 A1
(43) Pub. Date: Feb. 27, 2025

(54) CIRCUIT DESIGN WITH ENSEMBLE-BASED LEARNING

(71) Applicant: International Business Machines Corporation, Armonk, NY (US)

(72) Inventors: Shun Zhang, San Mateo, CA (US); Xin Zhang, Chappaqua, NY (US); Shaoze Fan, East Newark, NJ (US); Ningyuan Cao, Mishawaka, IN (US); Jing Li, Clifton, NJ (US); Xiaoxiao Guo, Mountain View, CA (US); Chuang Gan, Cambridge, MA (US)

(21) Appl. No.: 18/455,745

(22) Filed: Aug. 25, 2023

(51) Int. Cl. G06F 30/398; G06N 20/20

(52) U.S. Cl. CPC G06F 30/398; G06N 20/20

(57) ABSTRACT

Methods and systems for circuit generation include generating a circuit design. Paths are extracted from the circuit design, with the paths representing sequences of connected circuit components from one terminal of the circuit to another. The extracted paths are embedded as respective vectors in a latent space. A property of the circuit design is determined using an ensemble of trained surrogate models that accept a sequence of the vectors as input.

### STATEMENT REGARDING FEDERALLY SPONSORED RESEARCH OR DEVELOPMENT

This invention was made with Government support under Contract DE-AR0001210, awarded by Department of Energy. The Government has certain rights in this invention.

### BACKGROUND

The present invention generally relates to circuit design and, more particularly, to modeling properties of a circuit.

Designing modern electronic circuits is a complex process, and it can be difficult to predict the properties of a finished device. Properties such as power efficiency and output voltage may vary according to random variations that occur during fabrication, due to environmental factors, and due to interactions between components on the chip. Even with the aid of software simulation, simulating large circuits can be computationally inefficient.

### SUMMARY

A method for circuit generation includes generating a circuit design. Paths are extracted from the circuit design, with the paths representing sequences of connected circuit components from one terminal of the circuit to another. The extracted paths are embedded as respective vectors in a latent space. A property of the circuit design is determined using an ensemble of trained surrogate models that accept a sequence of the vectors as input.

A system for circuit generation includes a hardware processor and a memory that stores a computer program. When executed by the hardware processor, the computer program causes the hardware processor to generate a circuit design, to extract paths from the circuit design, with the paths representing sequences of connected circuit components from one terminal of the circuit to another, to embed the extracted paths as respective vectors in a latent space, and to determine a property of the circuit design using an ensemble of trained surrogate models that accept a sequence of the vectors as input.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a block/flow diagram of a method of generating and evaluating circuit designs without having to fully simulate the circuit designs, in accordance with an embodiment of the present invention;

FIG. 2 is a diagram illustrating the conversion of a circuit design to a graph, and then to a series of paths, in accordance with an embodiment of the present invention;

FIG. 3 is a block/flow diagram of a method of training an ensemble of models to evaluate properties of circuit designs, in accordance with an embodiment of the present invention;

FIG. 4 is a graph illustrating a comparison between the efficiencies of different approaches to evaluating the properties of a circuit design, in accordance with an embodiment of the present invention;

FIG. 5 is a graph illustrating a comparison between the efficiencies of different approaches to evaluating the properties of a circuit design, in accordance with an embodiment of the present invention;

FIG. 6 is a block/flow diagram of a method for fabricating circuits based on automatically generated circuit designs, in accordance with an embodiment of the present invention;

FIG. 7 is a block diagram of a computing system that can perform circuit generation and evaluation, in accordance with an embodiment of the present invention;

FIG. 8 is a diagram of an exemplary neural network architecture that may be used to implement part of the surrogate model, in accordance with an embodiment of the present invention; and

FIG. 9 is a diagram of an exemplary deep neural network architecture that may be used to implement part of the surrogate model, in accordance with an embodiment of the present invention.

### DETAILED DESCRIPTION

Active learning may be employed to automate circuit design and simulation, improving efficiency and accuracy by using a model to select informative samples for labeling. This leads to better performance and adaptability to changing design requirements. To that end, an ensemble-based model may be used that includes a transformer-based surrogate model, an upper confidence bound applied to trees (UCT) search, and an active learning strategy. A reward signal provided by the surrogate model is used to efficiently explore a topology space for circuits. The active learning selectively queries high-fidelity simulations to improve the accuracy of the surrogate model during exploration, thereby improving the quality of the output circuit.

To accomplish this, a circuit layout may be transformed to a suitable input to the surrogate model. Paths between external terminal ports may be extracted and encoded for the input. Rather than inputting these paths directly to the surrogate model, path-level representations are generated to convert the paths into embedded vectors of fixed length. The surrogate model may then process the paths as sequential inputs, such as with a transformer model where the paths are considered to be analogous to words. The surrogate model uses these inputs to generate a circuit-level representation. A multi-layer perceptron (MLP) portion of the surrogate model processes the circuit-level representation to generate the predicted properties of the circuit.

Based on the predicted circuit properties, changes may be made to the circuit to improve its performance before the circuit is fabricated. The deep learning approach described herein provides a substantial improvement over direct software simulation, making it possible to iterate and make improvements to the circuit more quickly.

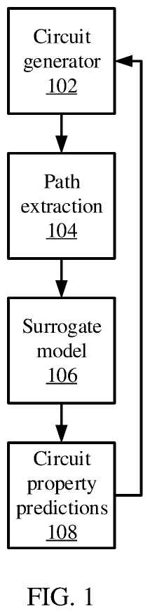

Referring now to FIG. 1, a block diagram is shown that illustrates how the present models are used in circuit generation. Block 102 generates a circuit design, for example using a UCT or Monte Carlo tree search method. At this stage, the circuit may be represented as a topology graph that indicates paths through components of the circuit and that has particular terminal nodes, such as Vᵢₙ, Vₒᵤₜ, and GND nodes. The nodes of the topology graph may represent components within the circuit, and the edges of the graph may represent transmission lines or other structures connecting the circuit components to one another.

UCT searching is similar to Monte Carlo tree searching and adapts locally to the effective smoothness of the tree. Upper confidence bounds guide the selection of a node, treating selection as a multi-armed bandit problem, where each trial selects between exploration and exploitation strategies. Exploitation seeks to generate the highest reward given the current knowledge of the reward function, while exploration seeks to obtain more information about the reward function to improve its future performance.

The generation of the circuit design in block 102 may include constraints. These constraints may represent circuits and structures that are to be avoided. An exemplary constraint may be to avoid directly connecting two ports of a device, which might otherwise cause a short-circuit. As a UCT tree search may generate a circuit by incrementally adding devices or connections, constraints may be checked when doing so to determine whether the change would violate a design rule. Thus, the UCT tree search may determine whether adding a given connection will produce a short-circuit, and may avoid such a change if so, moving on to the next design change. Block 102 may also generate circuit parameters, such as the duty cycle of the circuit. The UCT tree search may select a duty cycle value after the devices and connections are selected.

Path extraction 104 may first represent the topology graph as a set of paths, representing the different ways to traverse the topology graph from one terminal node to another. In some cases there may be parallel paths through the circuit, so that there may be multiple different paths that connect particular pairs of terminal nodes.

The path extraction 104 may further embed these individual paths to form vectors of fixed length, using a path embedding model that may include a long-short term memory (LSTM) network that the sequential information of a path input into a vector output. The LSTM embedding model first learns a device-level embedding that takes neighboring devices into consideration and then aggregates the information in device-level embeddings to obtain a path embedding. The output of the path embedding may include a parameter embedding concatenated with the path vector.

Such embedding models are useful for sequential information, such as textual information. Because the pathways of a circuit may be expressed in a sequential fashion, they may similarly be processed using sequential techniques to create a vector representation in a latent space. The latent space for circuit pathways captures similarity between different circuits, as similar vectors in the latent space correspond to similar circuits.

The path embeddings are used as input to the surrogate model 106. The surrogate model 106 may include a transformer network, followed by an MLP network. Because transformers take input as a sequence of vectors of equal lengths, the variable-length paths cannot be used directly as input, necessitating the use of embedded vectors.

While transformer networks were designed for natural language tasks, they are more generally applicable to sequential information where the context represented by the sequence is significant. The embedded path vectors are treated as being analogous to words in the context of the transformer network, with a sequence of path embeddings being provided as input to learn a circuit-level representation. The individual circuit components are not treated as being words because, unlike one-dimensional sequences of words in natural languages, the components of a circuit are laid out in a two-dimensional topology. In contrast, path embeddings better capture the topological features of the circuit. The circuit-level representation is used as input to the MLP network, which may be implemented as a set of fully connected neural network layers, to generate properties of the circuit 108 such as predicted efficiency and/or output voltage.

The predicted circuit properties are used to refine the circuit design by the circuit generator 102. The refinement may be guided by a reward function that expresses an optimization objective. This function may relate to efficiency and the voltage output of the circuit. Thus, the reward may be higher if the efficiency is higher and if the voltage output is close to a target voltage output, which depends on the task at hand.

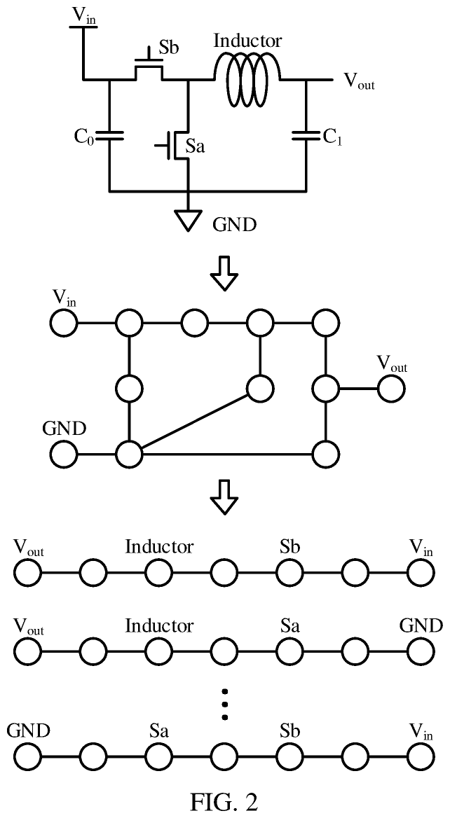

Referring now to FIG. 2, an example is shown for the representation of an electronic circuit as a set of paths. An initial circuit schematic may include a number of components, such as capacitors, inductors, and transistors, as well as terminal nodes Vᵢₙ, Vₒᵤₜ, and GND. The circuit may perform any appropriate function and the components may be defined as having respective properties, such as capacitances, inductances, and threshold voltages.

Path extraction 104 may first convert the circuit schematic into a graph representation, where each component is represented by a node. Branches in a path may also be represented as nodes. This graph representation may then be converted to a set of individual paths, each representing a different path between terminal nodes. These path sequences may be used as inputs to a path representation model to generate respective vector representations. During operation, it may be found that certain paths appear in high-efficiency circuits, while other paths appeal in low-efficiency circuits.

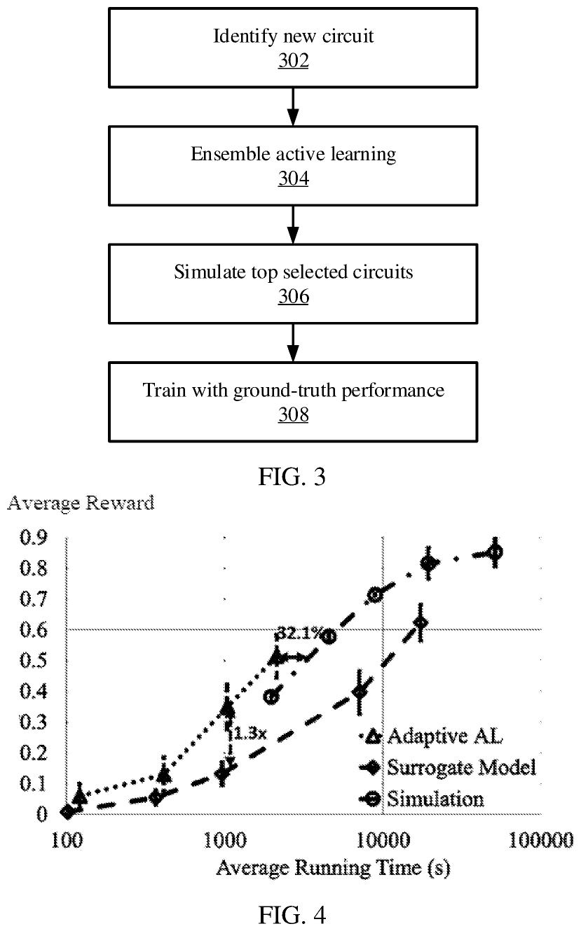

Referring now to FIG. 3, a method for training the surrogate model 106 is shown. Active learning is used to improve the efficiency of circuit space exploration by fine-tuning the surrogate model 106. Block 302 identifies a new circuit topology from the circuit generator 102 by comparing the output of the circuit generator 102 to previously generated circuit designs.

Block 304 selects proportional circuits using an ensemble active learning strategy. The search space for circuit topologies is large and discontinuous, so active learning is used to improve model accuracy and to optimize the searching direction, step-by-step, during circuit space exploration.

In particular, active learning can be used to improve accuracy using a small dataset for additional training. The dataset that is selected corresponds with the effectiveness of the active learning. The circuit space exploration may therefore be split into multiple phases. Active learning is performed once to improve the surrogate model 106 in each phase.

The term Cᵤ denotes newly observed circuits from a previous phase where the ground truth information is unknown. The term Cₖ is the set of data for which ground truth information is known, including the union of the original training data and circuits queried in previous active learning steps. A query objective S(Cᵤⁱ) may be determined for each newly observed circuit Cᵤⁱ, with a top proportion pᵤ of Cᵤ being selected for model training, where i is an index assigned when the new circuit is identified. Ground truth information may be determined by simulating the circuit to determine its efficiency and output voltage.

Query selection uses the prediction's upper confidence bound on a circuit to determine whether a given circuit should be evaluated. This involves the prediction of uncertainty information. Multiple surrogate models may therefore be used in a voting-based ensemble. For example, a single set of original training data may be used to train n different surrogate models F: {F⁰, . . . , Fⁿ} using different initial weights (e.g., being randomly initialized). The range of possible prediction values may be divided into a series of equally sized intervals. During circuit generation, a specific model F* may be used for evaluation.

During active learning 304, n predictions ε(Cᵤⁱ) may be generated for each circuit Cᵤⁱ. Each model votes on the interval for its prediction and the interval with the most votes is the one that has the predictions of the most models. The ensemble prediction ε(Cᵤⁱ) is the mean of the predictions in the most-voted interval, with the uncertainty being represented by the standard deviation of the predictions in that interval.

The utility of the observed circuit may be expressed as:

$$S ( {C}_{u}^{i} ) = ε ( {C}_{u}^{i} ) + α \cdot σ ( ε ( {C}_{u}^{i} ) )$$

where S(Cᵤⁱ) is the sum of the mean and standard deviation of the predictions in the most-voted interval. The parameter a adjusts the importance uncertainty when queried for active learning. To minimize the overhead of this active learning process, the newly observed circuits may be arranged in batches to compute the prediction of Cᵤ in parallel.

After selecting the newly observed circuits using the utility S(Cᵤⁱ), a circuit simulator may be used to obtain ground truth information in block 306. Now that the newly observed circuits have been labeled, they can be used to further train the surrogate models 106, along with a randomly sampled set of previously known training data examples Cₖ. In general, circuits with high S scores (e.g., scores above a threshold value) may be selected for simulation. If the ensemble models disagree on the properties of a circuit, simulating the circuit provides valuable information that can be used to improve the model. The UCT tree search may further track the rewards predicted by the surrogate. Once active learning is done and the surrogate model is updated, the rewards of the tree may be updated as well. Other types of active learning may be employed, such as the expected value of information (EVOI) or expected posterior utility (EPU), which compute the gap between the model's expected performance after selecting a circuit for active learning and the model's performance before active learning.

Referring now to FIG. 4, a graph shows a comparison between different approaches to determining circuit performance. The horizontal axis shows a logarithmic scale of the running time used to determine the circuit performance, while the vertical axis shows an average reward score. Three different approaches are shown, including using the surrogate model alone (shown as a dashed line), the surrogate model with active learning (shown as a dotted line), and a direct simulation. While the direct simulation outperforms the surrogate model alone, the addition of adaptive learning can achieve the same performance with a substantially lower computational cost (e.g., a reduction of 32.1%). For a given running time, the use of active learning provides a substantial improvement in the reward value over the surrogate model alone.

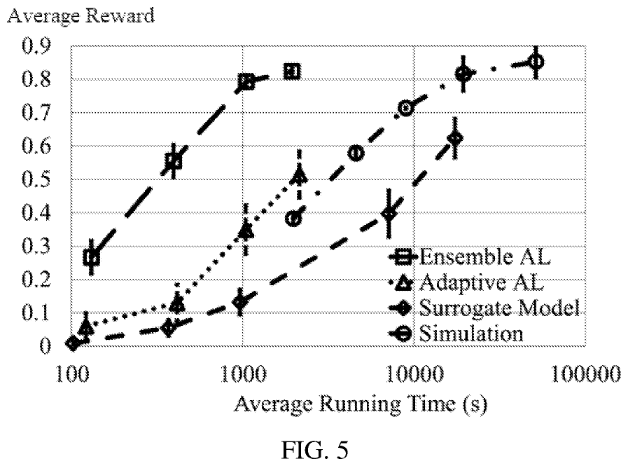

Referring now to FIG. 5, a graph shows a comparison between different approaches to determining circuit performance. As in FIG. 4, the horizontal axis shows a logarithmic scale of the running time used to determine the circuit performance, while the vertical axis shows an average reward score.

This graph further includes ensemble-based active learning as a further enhancement over the adaptive learning of FIG. 4. In particular, ensemble-based active learning uses multiple deep learning models for prediction to improve the performance at a given running time. The use of an ensemble of models reduces the overall design time for a circuit dramatically as compared to the exclusive use of direct simulation.

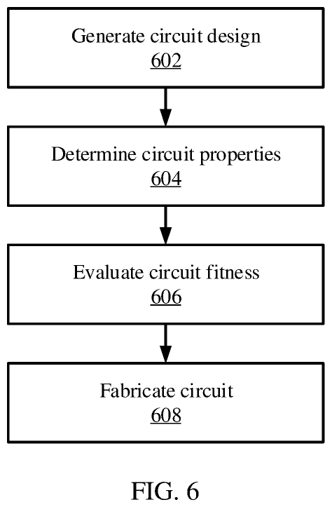

Referring now to FIG. 6, a method of fabricating a circuit is shown. Block 602 generates a circuit design. The circuit design may be generated as described above, using a UCT search, or may be generated by a human engineer. Block 604 determines one or more properties of the circuit design using the trained ensemble of models. This step can be performed much more quickly than if the circuit design were simulated to determine its properties.

The circuit design can then be evaluated for its fitness for an intended purpose at block 606. For example, the efficiency and output voltage of the circuit design may be compared to a range of acceptable values. If the properties of the circuit design fall within the range(s) of acceptable values, then block 608 may fabricate a circuit based on the circuit design using any appropriate fabrication method. In some cases, the fabrication of the circuit design may be fully automated, such as by using printed circuit board fabrication processes and pick-and-place component installation.

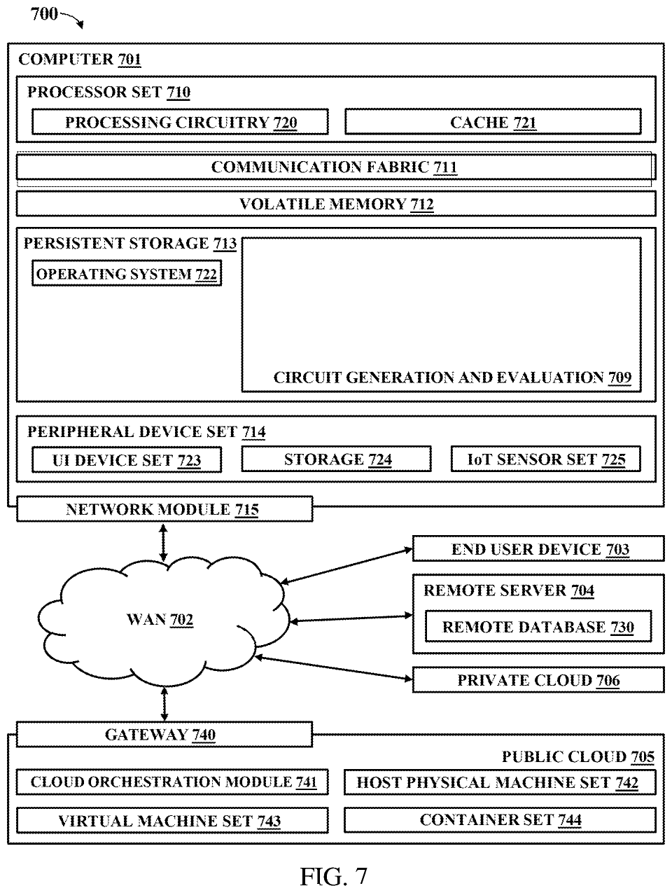

Referring now to FIG. 7, a computer system 701 is shown. Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 700 contains an example of an environment for the execution of at least some of the computer code involved in performing the inventive methods, such as circuit generation and evaluation 719. In addition to block 719, computing environment 700 includes, for example, computer 701, wide area network (WAN) 702, end user device (EUD) 703, remote server 704, public cloud 705, and private cloud 706. In this embodiment, computer 701 includes processor set 710 (including processing circuitry 720 and cache 721), communication fabric 711, volatile memory 712, persistent storage 713 (including operating system 722 and block 200, as identified above), peripheral device set 714 (including user interface (UI) device set 723, storage 724, and Internet of Things (IoT) sensor set 725), and network module 715. Remote server 704 includes remote database 730. Public cloud 705 includes gateway 740, cloud orchestration module 741, host physical machine set 742, virtual machine set 743, and container set 744.

COMPUTER 701 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 730. As is well understood in the art of computer technology, and depending upon the technology, performance of a computer-implemented method may be distributed among multiple computers and/or between multiple locations. On the other hand, in this presentation of computing environment 700, detailed discussion is focused on a single computer, specifically computer 701, to keep the presentation as simple as possible.

Computer 701 may be located in a cloud, even though it is not shown in a cloud in FIG. 7. On the other hand, computer 701 is not required to be in a cloud except to any extent as may be affirmatively indicated.

PROCESSOR SET 710 includes one, or more, computer processors of any type now known or to be developed in the future. Processing circuitry 720 may be distributed over multiple packages, for example, multiple, coordinated integrated circuit chips. Processing circuitry 720 may implement multiple processor threads and/or multiple processor cores. Cache 721 is memory that is located in the processor chip package(s) and is typically used for data or code that should be available for rapid access by the threads or cores running on processor set 710. Cache memories are typically organized into multiple levels depending upon relative proximity to the processing circuitry. Alternatively, some, or all, of the cache for the processor set may be located “off chip.” In some computing environments, processor set 710 may be designed for working with qubits and performing quantum computing.

Computer readable program instructions are typically loaded onto computer 701 to cause a series of operational steps to be performed by processor set 710 of computer 701 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 721 and the other storage media discussed below. The program instructions, and associated data, are accessed by processor set 710 to control and direct performance of the inventive methods. In computing environment 700, at least some of the instructions for performing the inventive methods may be stored in block 200 in persistent storage 713.

COMMUNICATION FABRIC 711 is the signal conduction path that allows the various components of computer 701 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 712 is any type of volatile memory now known or to be developed in the future. Examples include dynamic type random access memory (RAM) or static type RAM. Typically, volatile memory 712 is characterized by random access, but this is not required unless affirmatively indicated. In computer 701, the volatile memory 712 is located in a single package and is internal to computer 701, but, alternatively or additionally, the volatile memory may be distributed over multiple packages and/or located externally with respect to computer 701.

PERSISTENT STORAGE 713 is any form of non-volatile storage for computers that is now known or to be developed in the future. The non-volatility of this storage means that the stored data is maintained regardless of whether power is being supplied to computer 701 and/or directly to persistent storage 713. Persistent storage 713 may be a read only memory (ROM), but typically at least a portion of the persistent storage allows writing of data, deletion of data and re-writing of data. Some familiar forms of persistent storage include magnetic disks and solid state storage devices. Operating system 722 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 714 includes the set of peripheral devices of computer 701. Data communication connections between the peripheral devices and the other components of computer 701 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 723 may include components such as a display screen, speaker, microphone, wearable devices (such as goggles and smart watches), keyboard, mouse, printer, touchpad, game controllers, and haptic devices. Storage 724 is external storage, such as an external hard drive, or insertable storage, such as an SD card. Storage 724 may be persistent and/or volatile. In some embodiments, storage 724 may take the form of a quantum computing storage device for storing data in the form of qubits. In embodiments where computer 701 is required to have a large amount of storage (for example, where computer 701 locally stores and manages a large database) then this storage may be provided by peripheral storage devices designed for storing very large amounts of data, such as a storage area network (SAN) that is shared by multiple, geographically distributed computers. IoT sensor set 725 is made up of sensors that can be used in Internet of Things applications. For example, one sensor may be a thermometer and another sensor may be a motion detector.

NETWORK MODULE 715 is the collection of computer software, hardware, and firmware that allows computer 701 to communicate with other computers through WAN 702. Network module 715 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 715 are performed on the same physical hardware device. In other embodiments (for example, embodiments that utilize software-defined networking (SDN)), the control functions and the forwarding functions of network module 715 are performed on physically separate devices, such that the control functions manage several different network hardware devices.

Computer readable program instructions for performing the inventive methods can typically be downloaded to computer 701 from an external computer or external storage device through a network adapter card or network interface included in network module 715.

WAN 702 is any wide area network (for example, the internet) capable of communicating computer data over non-local distances by any technology for communicating computer data, now known or to be developed in the future. In some embodiments, the WAN 012 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 703 is any computer system that is used and controlled by an end user (for example, a customer of an enterprise that operates computer 701), and may take any of the forms discussed above in connection with computer 701. EUD 703 typically receives helpful and useful data from the operations of computer 701. For example, in a hypothetical case where computer 701 is designed to provide a recommendation to an end user, this recommendation would typically be communicated from network module 715 of computer 701 through WAN 702 to EUD 703. In this way, EUD 703 can display, or otherwise present, the recommendation to an end user. In some embodiments, EUD 703 may be a client device, such as thin client, heavy client, mainframe computer, desktop computer and so on.

REMOTE SERVER 704 is any computer system that serves at least some data and/or functionality to computer 701. Remote server 704 may be controlled and used by the same entity that operates computer 701. Remote server 704 represents the machine(s) that collect and store helpful and useful data for use by other computers, such as computer 701. For example, in a hypothetical case where computer 701 is designed and programmed to provide a recommendation based on historical data, then this historical data may be provided to computer 701 from remote database 730 of remote server 704.

PUBLIC CLOUD 705 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 705 is performed by the computer hardware and/or software of cloud orchestration module 741. The computing resources provided by public cloud 705 are typically implemented by virtual computing environments that run on various computers making up the computers of host physical machine set 742, which is the universe of physical computers in and/or available to public cloud 705. The virtual computing environments (VCEs) typically take the form of virtual machines from virtual machine set 743 and/or containers from container set 744. It is understood that these VCEs may be stored as images and may be transferred among and between the various physical machine hosts, either as images or after instantiation of the VCE. Cloud orchestration module 741 manages the transfer and storage of images, deploys new instantiations of VCEs and manages active instantiations of VCE deployments. Gateway 740 is the collection of computer software, hardware, and firmware that allows public cloud 705 to communicate through WAN 702.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 706 is similar to public cloud 705, except that the computing resources are only available for use by a single enterprise. While private cloud 706 is depicted as being in communication with WAN 702, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 705 and private cloud 706 are both part of a larger hybrid cloud.

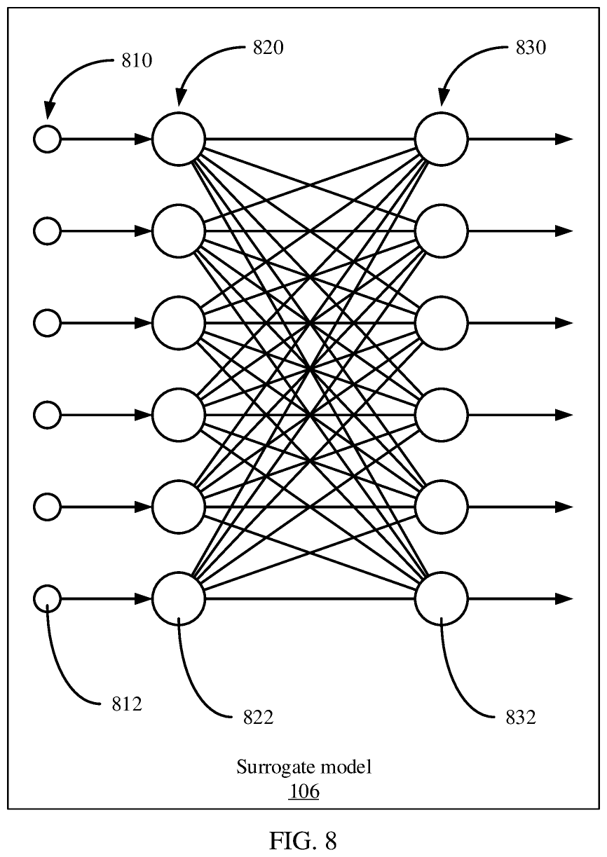

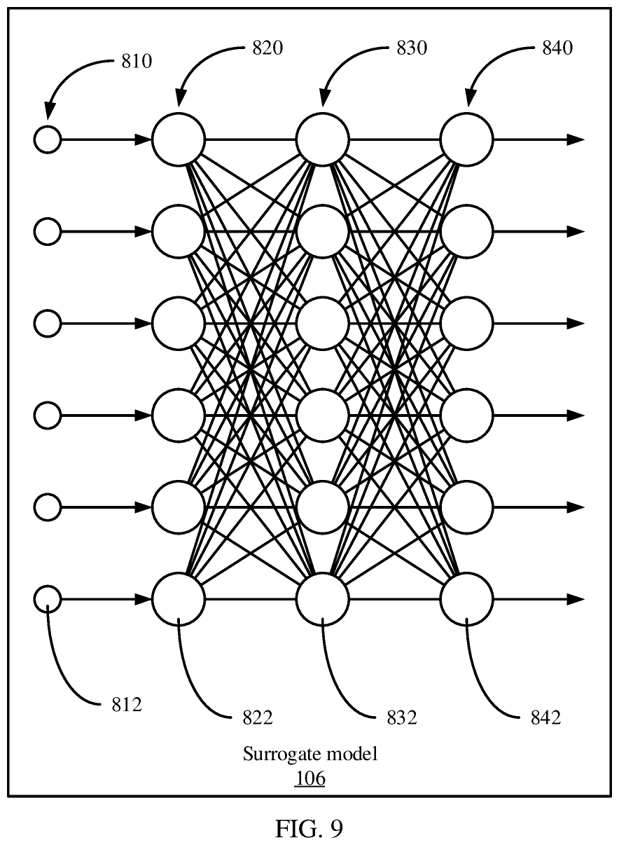

Referring now to FIGS. 8 and 9, exemplary neural network architectures are shown, which may be used to implement parts of the present models, such as tuned model 504. A neural network is a generalized system that improves its functioning and accuracy through exposure to additional empirical data. The neural network becomes trained by exposure to the empirical data. During training, the neural network stores and adjusts a plurality of weights that are applied to the incoming empirical data. By applying the adjusted weights to the data, the data can be identified as belonging to a particular predefined class from a set of classes or a probability that the inputted data belongs to each of the classes can be outputted.

The empirical data, also known as training data, from a set of examples can be formatted as a string of values and fed into the input of the neural network. Each example may be associated with a known result or output. Each example can be represented as a pair, (x, y), where x represents the input data and y represents the known output. The input data may include a variety of different data types, and may include multiple distinct values. The network can have one input node for each value making up the example's input data, and a separate weight can be applied to each input value. The input data can, for example, be formatted as a vector, an array, or a string depending on the architecture of the neural network being constructed and trained.

The neural network “learns” by comparing the neural network output generated from the input data to the known values of the examples, and adjusting the stored weights to minimize the differences between the output values and the known values. The adjustments may be made to the stored weights through back propagation, where the effect of the weights on the output values may be determined by calculating the mathematical gradient and adjusting the weights in a manner that shifts the output towards a minimum difference. This optimization, referred to as a gradient descent approach, is a non-limiting example of how training may be performed. A subset of examples with known values that were not used for training can be used to test and validate the accuracy of the neural network.

During operation, the trained neural network can be used on new data that was not previously used in training or validation through generalization. The adjusted weights of the neural network can be applied to the new data, where the weights estimate a function developed from the training examples. The parameters of the estimated function which are captured by the weights are based on statistical inference.

In layered neural networks, nodes are arranged in the form of layers. An exemplary simple neural network has an input layer 820 of source nodes 822, and a single computation layer 830 having one or more computation nodes 832 that also act as output nodes, where there is a single computation node 832 for each possible category into which the input example could be classified. An input layer 820 can have a number of source nodes 822 equal to the number of data values 812 in the input data 810. The data values 812 in the input data 810 can be represented as a column vector. Each computation node 832 in the computation layer 830 generates a linear combination of weighted values from the input data 810 fed into input nodes 820, and applies a non-linear activation function that is differentiable to the sum. The exemplary simple neural network can perform classification on linearly separable examples (e.g., patterns).

A deep neural network, such as a multilayer perceptron, can have an input layer 820 of source nodes 822, one or more computation layer(s) 830 having one or more computation nodes 832, and an output layer 840, where there is a single output node 842 for each possible category into which the input example could be classified. An input layer 820 can have a number of source nodes 822 equal to the number of data values 812 in the input data 810. The computation nodes 832 in the computation layer(s) 830 can also be referred to as hidden layers, because they are between the source nodes 822 and output node(s) 842 and are not directly observed. Each node 832, 842 in a computation layer generates a linear combination of weighted values from the values output from the nodes in a previous layer, and applies a non-linear activation function that is differentiable over the range of the linear combination. The weights applied to the value from each previous node can be denoted, for example, by w₁, w₂, . . . wₙ₋₁, wₙ. The output layer provides the overall response of the network to the inputted data. A deep neural network can be fully connected, where each node in a computational layer is connected to all other nodes in the previous layer, or may have other configurations of connections between layers. If links between nodes are missing, the network is referred to as partially connected.

As employed herein, the term “hardware processor subsystem” or “hardware processor” can refer to a processor, memory, software or combinations thereof that cooperate to perform one or more specific tasks. In useful embodiments, the hardware processor subsystem can include one or more data processing elements (e.g., logic circuits, processing circuits, instruction execution devices, etc.). The one or more data processing elements can be included in a central processing unit, a graphics processing unit, and/or a separate processor- or computing element-based controller (e.g., logic gates, etc.). The hardware processor subsystem can include one or more on-board memories (e.g., caches, dedicated memory arrays, read only memory, etc.). In some embodiments, the hardware processor subsystem can include one or more memories that can be on or off board or that can be dedicated for use by the hardware processor subsystem (e.g., ROM, RAM, basic input/output system (BIOS), etc.).

In some embodiments, the hardware processor subsystem can include and execute one or more software elements. The one or more software elements can include an operating system and/or one or more applications and/or specific code to achieve a specified result.

In other embodiments, the hardware processor subsystem can include dedicated, specialized circuitry that performs one or more electronic processing functions to achieve a specified result. Such circuitry can include one or more application-specific integrated circuits (ASICs), FPGAs, and/or PLAs.

These and other variations of a hardware processor subsystem are also contemplated in accordance with embodiments of the present invention.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Having described preferred embodiments of circuit design with ensemble-based learning (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A computer-implemented method for circuit generation, comprising:
generating a circuit design;
extracting paths from the circuit design, with the paths representing sequences of connected circuit components from one terminal of the circuit to another;
embedding the extracted paths as respective vectors in a latent space; and
determining a property of the circuit design using an ensemble of trained surrogate models that accept a sequence of the vectors as input.

2. The method of claim 1, wherein generating the circuit design uses an upper confidence bound applied to trees (UCT) search.

3. The method of claim 2, wherein generating the circuit design further constrains generated circuit designs according to a design rule.

4. The method of claim 1, wherein determining the property of the circuit design includes determining at least one of an efficiency and an output voltage.

5. The method of claim 1, further comprising determining that the circuit design is a new circuit design based on an uncertainty of the trained surrogate models.

6. The method of claim 5, further comprising simulating the new circuit design to determine a ground truth property of the new circuit design and updating the surrogate models using the ground truth property.

7. The method of claim 1, wherein determining the property of the circuit design includes:
generating predictions by the surrogate models;
identifying an interval for each of the predictions; and
calculating a mean of predictions in an interval that is selected most by the surrogate models as the property.

8. The method of claim 7, further comprising calculating an uncertainty value as a standard deviation of the predictions in the interval that is selected most by the surrogate models.

9. The method of claim 1, further comprising evaluating a fitness of the circuit design for an intended purpose based on the property.

10. The method of claim 9, further comprising fabricating the circuit design responsive to determining that the circuit design is fit for the intended purpose.

11. A computer program product for circuit generation, the computer program product comprising a computer readable storage medium having program instructions embodied therewith, the program instructions being executable by a hardware processor to cause the hardware processor to:
generate a circuit design;
extract paths from the circuit design, with the paths representing sequences of connected circuit components from one terminal of the circuit to another;
embed the extracted paths as respective vectors in a latent space; and
determine a property of the circuit design using an ensemble of trained surrogate models that accept a sequence of the vectors as input.

12. A system for circuit generation, comprising:
a hardware processor; and
a memory that stores a computer program which, when executed by the hardware processor, causes the hardware processor to:
generate a circuit design;
extract paths from the circuit design, with the paths representing sequences of connected circuit components from one terminal of the circuit to another;
embed the extracted paths as respective vectors in a latent space; and
determine a property of the circuit design using an ensemble of trained surrogate models that accept a sequence of the vectors as input.

13. The system of claim 12, wherein the computer program further causes the hardware processor to use an upper confidence bound applied to trees (UCT) search to generate the circuit design.

14. The system of claim 13, wherein the computer program further causes the hardware processor to constrain generated circuit designs according to a design rule.

15. The system of claim 12, wherein the computer program further causes the hardware processor to determine at least one of an efficiency and an output voltage as the property.

16. The system of claim 12, wherein the computer program further causes the hardware processor to determine that the circuit design is a new circuit design based on an uncertainty of the trained surrogate models.

17. The system of claim 16, wherein the computer program further causes the hardware processor to simulate the new circuit design to determine a ground truth property of the new circuit design and updating the surrogate models using the ground truth property.

18. The system of claim 12, wherein the computer program further causes the hardware processor to:
generate predictions by the surrogate models;
identify an interval for each of the predictions; and
calculate a mean of predictions in an interval that is selected most by the surrogate models as the property.

19. The system of claim 18, wherein the computer program further causes the hardware processor to calculate an uncertainty value as a standard deviation of the predictions in the interval that is selected most by the surrogate models.

20. The system of claim 12, wherein the computer program further causes the hardware processor to evaluate a fitness of the circuit design for an intended purpose based on the property and to fabricate the circuit design responsive to determining that the circuit design is fit for the intended purpose.
